(19) United States
(12) Patent Application Publication
(10) Pub. No.: US 2019/0033673 A1
(43) Pub. Date: Jan. 31, 2019

(54) ARRAY SUBSTRATE, DISPLAY PANEL AND DISPLAY DEVICE

(71) Applicant: BOE TECHNOLOGY GROUP CO., LTD., Beijing (CN)

(72) Inventor: Ning CHEN, Beijing (CN)

(21) Appl. No.: 15/778,701

(22) PCT Filed: Oct. 16, 2017
(86) PCT No.: PCT/CN2017/106325

§ 371 Date: May 24, 2018

(30) Foreign Application Priority Data
Jan. 16, 2017 (CN) 201710032479.0

(51) Int. Cl. G02F 1/1362; G02F 1/1333; H05K 1/11

(52) U.S. Cl. CPC G02F 1/136227; G02F 1/136286; G02F 2001/136295; H05K 1/118; G02F 1/133305

(57) ABSTRACT

The present disclosure provides an array substrate, a display panel and a display device. The array substrate includes: a base substrate, a plurality of signal lines disposed on the base substrate and located in a display area, and a plurality of signal line traces in one-to-one correspondence with the plurality of signal lines, wherein each of the plurality of signal lines are electrically connected to a corresponding signal line trace through a conductive via hole, and the plurality of signal line traces are located on a side of the base substrate facing away from the plurality of signal lines.

### RELATED APPLICATION

The present application is the U.S. national phase entry of PCT/CN2017/106325, with an international filing date of Oct. 16, 2017, which claims the benefit of Chinese Patent Application No. 201710032479.0, filed on Jan. 16, 2017, the entire disclosure of which is incorporated herein by reference.

### FIELD

The present disclosure relates to the field of display technologies, and particularly to an array substrate, a display panel and a display device.

### BACKGROUND

In recent years, liquid crystal display devices have been widely used in many electronic products in place of conventional cathode ray tube displays due to their advantages such as being thin and light, saving power, generating no radiation, and so on. In the fields of integrated circuit package and semiconductor display, electronic devices with small size, large capacity, multiple pins, and high density are continuously obtained. Therefore, it is an inevitable trend in the industry to develop driving circuit welding and packaging technologies in a liquid crystal display device that is more integrated, thinner and lighter.

At present, structures mainly used in liquid crystal display devices for carrying and packaging electrical components include a Printed Circuit Board (PCB), a Flexible Printed Circuit (FPC), a Tape Carrier Package (TCP), Chip on Film (COF), and the like. However, these structures have different degrees of limitation in terms of pin integration, narrow pitch, flexibility, cost, etc.

Therefore, how to realize a narrow frame, reduce space occupied by boundary-integrated electrical components, and make a module thin and light is a technical problem to be urgently solved by those skilled in the art.

### SUMMARY

In view of the above, embodiments of the present disclosure provide an array substrate, a display panel, and a display device, which can at least partially alleviate or even eliminate one or more of the defects mentioned above.

Accordingly, embodiments of the present disclosure provide an array substrate comprising: a base substrate; a plurality of signal lines disposed on the base substrate and located in a display area. The array substrate further comprises a plurality of signal line traces in one-to-one correspondence with the plurality of signal lines, wherein each of the plurality of signal lines is electrically connected to a corresponding signal line trace through a conductive via hole, and the plurality of signal line traces are located on a side of the base substrate facing away from the plurality of signal lines.

In some exemplary embodiments, in the above array substrate provided by embodiments of the present disclosure, the conductive via hole is arranged at an edge of the display area.

In some exemplary embodiments, in the above array substrate provided by embodiments of the present disclosure, an entire interior of the conductive via hole is filled with a metallic material.

In some exemplary embodiments, in the above array substrate provided by embodiments of the present disclosure, an interior of the conductive via hole is filled with a metallic material and a high-molecular polymer organic material stacked on each other.

In some exemplary embodiments, in the above array substrate provided by embodiments of the present disclosure, the plurality of signal lines are gate lines, and the plurality of signal line traces are gate line traces.

In some exemplary embodiments, in the above array substrate provided by embodiments of the present disclosure, the plurality of signal lines are data lines, and the plurality of signal line traces are data line traces.

In some exemplary embodiments, in the above array substrate provided by embodiments of the present disclosure, the base substrate is a glass substrate.

In some exemplary embodiments, in the above array substrate provided by embodiments of the present disclosure, the conductive via hole is formed by the steps of: forming a via hole in the base substrate; and filling the via hole with a metallic material by plasma sputtering or pasting.

In some exemplary embodiments, in the above array substrate provided by embodiments of the present disclosure, the conductive via hole is formed by the steps of: forming a via hole in the base substrate; and filling the via hole with a stack of a metallic material and a high-molecular polymer organic material by plasma sputtering.

In some exemplary embodiments, in the above array substrate provided by embodiments of the present disclosure, the high-molecular polymer organic material includes polydimethylsiloxane.

Embodiments of the present disclosure further provide a display panel comprising any of the array substrates provided by embodiments of the present disclosure. The display panel further comprises a driving chip, a flexible circuit board and a printed circuit board. At least one of the driving chip, the flexible circuit board, and the printed circuit board is located on a side of the base substrate of the array substrate facing away from the plurality of signal lines in the array substrate.

In some exemplary embodiments, in the above display panel provided by embodiments of the present disclosure, each of the plurality of signal line traces is electrically connected to a pin of the driving chip, and the driving chip is electrically connected to the printed circuit board through the flexible circuit board.

In some exemplary embodiments, in the above display panel provided by embodiments of the present disclosure, each of the plurality of signal line traces is electrically connected to the printed circuit board directly through the flexible circuit board, and the driving chip is integrated on the printed circuit board.

In some exemplary embodiments, in the above display panel provided by embodiments of the present disclosure, the driving chip is one of a gate driving chip and a source driving chip.

Embodiments of the present disclosure further provide a display device comprising any of the display panels provided by embodiments of the present disclosure.

### BRIEF DESCRIPTION OF DRAWINGS

FIG. 1 is a schematic structural view of a typical array substrate; and

FIG. 2 is a schematic structural view of an array substrate provided by embodiments of the present disclosure.

### DETAILED DESCRIPTION

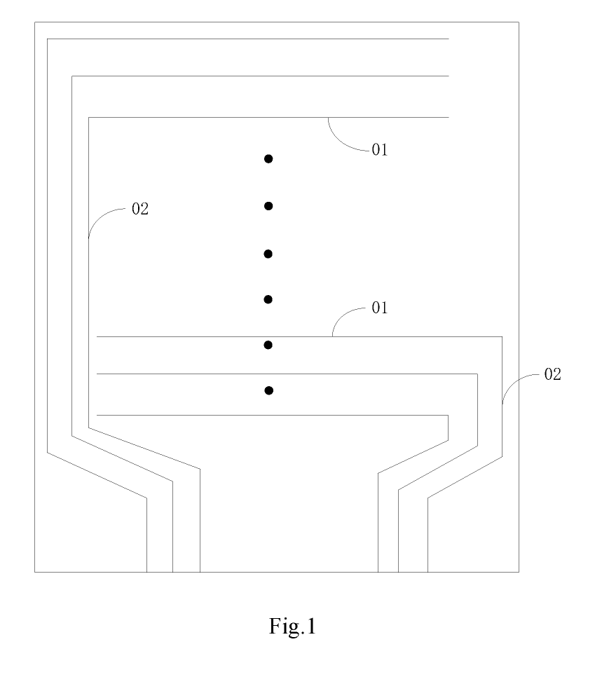

A typical array substrate in a liquid crystal display device, as shown in FIG. 1, comprises a plurality of gate lines 01 and a plurality of data lines (not shown) located in a display area and arranged in an intersecting and insulating manner. One end of each gate line 01 is provided with a gate line trace 02 in one-to-one correspondence with the gate lines 01. Similarly, one end of each data line is provided with a data line trace in one-to-one correspondence with the data lines. Generally, both the gate line traces 02 and the data line traces are located in a frame wiring area, which will make the frame of the display panel wider.

Through Glass Via (TGV) technology is a key technology for manufacturing a three-dimensional integrated circuit. The TGV technology is a technology which uses laser light to bore a via hole with a width of several tens to several hundreds of μm in a glass with a thickness of several hundreds of μm, and then fills the via hole with a metal by means of plasma sputtering or pasting for electrical connection of electronic components. The way of integrating wafer stacks by vertical conduction can achieve the purpose of electrical interconnection between wafers, and is therefore very suitable for 3D package, which is a promising package and integration method.

In the array substrate, the display panel, and the display device provided by embodiments of the present disclosure, the TGV technology is utilized to build a panel module so as to realize an effect of narrow frame or even no frame.

Specific implementations of the array substrate, the display panel, and the display device provided by embodiments of the present disclosure will be described in detail below with reference to the accompanying drawings.

It is to be pointed out that the size and the shape of each structure in the drawings do not reflect the true scale of the array substrate, but only for the purpose of schematically illustrating the present disclosure.

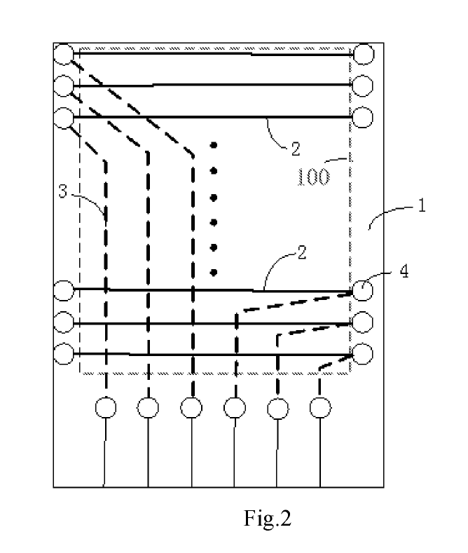

Embodiments of the present disclosure provide an array substrate, as shown in FIG. 2, comprising a base substrate 1, and a plurality of signal lines 2 disposed on the base substrate 1 and located in a display area 100. The array substrate further comprises a plurality of signal line traces 3 in one-to-one correspondence with the plurality of signal lines 2. Each signal line 2 is electrically connected to a corresponding signal line trace 3 through a conductive via hole 4, and the plurality of signal line traces 3 are located on a side of the base substrate 1 facing away from the plurality of signal lines 2. Since FIG. 2 shows the signal lines 2 located on a side of the base substrate 1 in a top view, the signal line traces 3 located on another side (which is the back side in the orientation of FIG. 2) of the base substrate 1 facing away from the signal lines 2 are shown by dashed lines in FIG. 2.

It is to be noted that the above-mentioned conductive via hole could by a via hole formed by the TGV technology. Since the signal line is located in the display area and is electrically connected to the signal line trace through the conductive via hole, the area where the signal line trace resides may be the display area, or be close to the display area, so that an effect of narrow frame or even no frame can be realized.

The above array substrate provided by embodiments of the present disclosure comprises a base substrate, a plurality of signal lines disposed on the base substrate and located in a display area, and a plurality of signal line traces in one-to-one correspondence with the plurality of signal lines, wherein each of the plurality of signal lines is electrically connected to a corresponding signal line trace through a conductive via hole, and the plurality of signal line traces are located on a side of the base substrate facing away from the plurality of signal lines. In the above array substrate provided by embodiments of the present disclosure, by arranging the conductive via hole, the plurality of signal line traces electrically connected to the plurality of signal lines are particularly disposed on a side of the base substrate facing away from the plurality of signal lines, thus an effect of narrow frame or even no frame can be realized, and the cost can be reduced.

In the above array substrate provided in embodiments of the present disclosure, the base substrate may be set as a glass substrate.

Further, in the above array substrate provided by embodiments of the present disclosure, in order to ensure the realization of a narrow frame, as shown in FIG. 2, the respective conductive via holes 4 may be arranged at an edge of the display area 100, respectively, and it may also be considered that the respective conductive via holes 4 may be located on two sides of the display area 100, respectively, so that the display effect is not affected and the wiring is simple.

In the above array substrate provided by embodiments of the present disclosure, the entire interior of the conductive via hole may be filled with a metallic material. Alternatively, the interior of the conductive via hole may be filled with a metallic material and a high-molecular polymer organic material which are stacked on each other.

Specifically, in a manufacturing process of forming a conductive via hole pattern, i.e. when a hole is bored and filled, the via hole may be filled with metal ions plasmas, and may also be filled by pasting copper (Cu). For plasma filling, when the via hole cannot be completely filled with a metal element, the hollow portion that is unfilled may also be filled with high-molecular polymers such as polydimethylsiloxane (PDMS), so as to ensure mechanically stable performance. It is to be noted that hole filling ratio, hole impedance, via hole, wiring, packaging, etc are all important design parameters and require reliability design.

In the above array substrate provided by embodiments of the present disclosure, specifically, the signal line may be a gate line, and the signal line trace may be a gate line trace accordingly. Alternatively, the signal line may be a data line, and the signal line trace may be a data line trace accordingly. Specific types of the signal line and the signal line trace can be determined according to actual conditions, and are not limited here.

The array substrate provided by embodiments of the present disclosure generally further comprises other film layer structures such as an electrode layer, an insulating layer, a passivation layer, and the like, as well as structures such as a thin film transistor formed on the base substrate. These specific structures can be implemented in various ways and are not limited here.

Embodiments of the present disclosure further provide a display panel. The display panel comprises the above array substrate provided by embodiments of the present disclosure, a driving chip (IC), a flexible circuit board (FPC), and a printed circuit board (PCB). At least one of the driving chip (IC), the flexible circuit board (FPC), and the printed circuit board (PCB) may be located on a side of the base substrate in the array substrate facing away from the signal lines in the array substrate.

Since in the array substrate in the above display panel provided by embodiments of the present disclosure, the signal line traces electrically connected to the signal lines are particularly disposed on a side of the base substrate facing away from the signal lines by arranging the conductive via holes, an effect of narrow frame or even no frame can be realized, and the cost can be reduced. Since at least one of the driving chip, the flexible circuit board, and the printed circuit board is particularly disposed on a side of the base substrate in the array substrate facing away from the signal lines, fanout area and the space occupied by boundary-integrated electrical components can be reduced, thereby making the module small, thin and light. When the driving chip, the flexible circuit board, and the printed circuit board are all disposed on a side of the base substrate in the array substrate facing away from the signal lines, an optimized effect can be achieved, and in that case, the boundary-integrated electrical components occupy the least space.

In the above display panel provided by embodiments of the present disclosure, each signal line trace can be electrically connected to a pin of the driving chip, and the driving chip is electrically connected to the printed circuit board through the flexible circuit board.

Alternatively, in the above display panel provided by embodiments of the present disclosure, each signal line trace may be electrically connected to the printed circuit board directly through the flexible circuit board, and the driving chip is integrated on the printed circuit board.

In the above display panel provided by embodiments of the present disclosure, when the signal line in the array substrate is a gate line and the signal line trace is a gate line trace, the driving chip may be a gate driving chip. Alternatively, when the signal line in the array substrate is a data line and the signal line trace is a data line trace, the driving chip may be a source driving chip.

It is to be noted that, for the array substrate and the display panel provided by embodiments of the present disclosure, four aspects of failure need to be considered: thermal mechanical failure (thermal fatigue cracking, brittle crack, elastic deformation, etc); electrical failure (ESD, electromigration, signal delay caused by crosstalk, etc); chemical failure (corrosion, intermetallic diffusion). In addition, reliability testing further needs to be performed on the scheme of forming a conductive via hole pattern, including: thermal cycle testing, temperature and humidity testing, thermal shock testing, short-term power-on switching cycle, impedance testing and crosstalk testing under different conditions for forming a conductive via hole pattern, so that normal operation of the device can be ensured.

Embodiments of the present disclosure further provide a display device comprising the above display panel provided by embodiments of the present disclosure. The display device may be any product or component having display function such as a mobile phone, a tablet computer, a television, a display, a notebook computer, a digital photo frame, a navigator, and the like. Other essential components being included in the display device is understandable by those ordinarily skilled in the art, which are not described here, and should not be taken as limitation to the present disclosure. For the implementation of the display device, reference can be made to the above embodiments of the display panel and the array substrate, and repeated description is omitted.

Embodiments of the present disclosure provide an array substrate, a display panel, and a display device. The array substrate comprises a base substrate, a plurality of signal lines disposed on the base substrate and located in a display area, and a plurality of signal line traces in one-to-one correspondence with the plurality of signal lines. Each of the plurality of signal lines is electrically connected to a corresponding signal line trace through a conductive via hole, and the plurality of signal line traces are located on a side of the base substrate facing away from the plurality of signal lines. Since in the above array substrate provided by embodiments of the present disclosure, the plurality of signal line traces electrically connected to the plurality of signal lines are particularly disposed on a side of the base substrate facing away from the plurality of signal lines by arranging the conductive via hole, an effect of narrow frame or even no frame can be realized, and the cost can be reduced. The display panel comprises the above array substrate, and further comprises a driving chip, a flexible circuit board, and a printed circuit board. Each signal line trace in the array substrate is electrically connected to a pin of the driving chip, and the driving chip is electrically connected to the printed circuit board through the flexible circuit board. Since in the array substrate in the above display panel provided by embodiments of the present disclosure, the plurality of signal line traces electrically connected to the plurality of signal lines are particularly disposed on a side of the base substrate facing away from the plurality of signal lines by arranging the conductive via hole, and at least one of the driving chip, the flexible circuit board and the printed circuit board are disposed on a side of the base substrate in the array substrate facing away from the plurality of signal lines, fanout area and the space occupied by boundary-integrated electrical components can be reduced, thereby making the module small, thin and light.

Obviously, those skilled in the art can make various modifications and variations to the present disclosure without departing from the spirit and scope thereof. In this way, if these modifications and variations to the present disclosure pertain to the scope of the claims of the present disclosure and equivalent technologies thereof, the present disclosure also intends to encompass these modifications and variations.

1. An array substrate comprising:
a base substrate;
a plurality of signal lines disposed on the base substrate and located in a display area; and
a plurality of signal line traces in one-to-one correspondence with the plurality of signal lines,
wherein each of the plurality of signal lines is electrically connected to a corresponding signal line trace through a conductive via hole, and the plurality of signal line traces are located on a side of the base substrate facing away from the plurality of signal lines.

2. The array substrate according to claim 1, wherein the conductive via hole is arranged at an edge of the display area.

3. The array substrate according to claim 2, wherein an entire interior of the conductive via hole is filled with a metallic material.

4. The array substrate according to claim 2, wherein an interior of the conductive via hole is filled with a metallic material and a high-molecular polymer organic material stacked on each other.

5. The array substrate according to claim 1, wherein the plurality of signal lines are gate lines, and the plurality of signal line traces are gate line traces.

6. The array substrate according to claim 1, wherein the plurality of signal lines are data lines, and the plurality of signal line traces are data line traces.

7. The array substrate according to claim 1, wherein the base substrate is a glass substrate.

8. The array substrate according to claim 1, wherein the conductive via hole is formed by the steps of:
forming a via hole in the base substrate; and
filling the via hole with a metallic material by plasma sputtering or pasting.

9. The array substrate according to claim 1, wherein the conductive via hole is formed by the steps of:
forming a via hole in the base substrate; and
filling the via hole with a stack of a metallic material and a high-molecular polymer organic material by plasma sputtering.

10. The array substrate according to claim 4, wherein the high-molecular polymer organic material includes polydimethylsiloxane.

11. A display panel comprising:
the array substrate according to claim 1; and
a driving chip, a flexible circuit board and a printed circuit board, wherein
at least one of the driving chip, the flexible circuit board, and the printed circuit board is located on a side of the base substrate of the array substrate facing away from the plurality of signal lines in the array substrate.

12. The display panel according to claim 11, wherein each of the plurality of signal line traces is electrically connected to a pin of the driving chip, and the driving chip is electrically connected to the printed circuit board through the flexible circuit board.

13. The display panel according to claim 11, wherein each of the plurality of signal line traces is electrically connected to the printed circuit board directly through the flexible circuit board, and the driving chip is integrated on the printed circuit board.

14. The display panel according to claim 11, wherein the driving chip is a gate driving chip.

15. The display panel according to claim 11, wherein the driving chip is a source driving chip.

16. A display device comprising the display panel according to claim 11.

17. The array substrate according to claim 9, wherein the high-molecular polymer organic material includes polydimethylsiloxane.

18. The display panel according to claim 11, wherein the conductive via hole is arranged at an edge of the display area.

19. The display panel according to claim 18, wherein an entire interior of the conductive via hole is filled with a metallic material.

20. The display panel according to claim 18, wherein an interior of the conductive via hole is filled with a metallic material and a high-molecular polymer organic material stacked on each other.
